(19) United States
(12) Patent Application Publication
(10) Pub. No.: US 2009/0301550 A1
(43) Pub. Date: Dec. 10, 2009

(54) FOCUSED ACOUSTIC PRINTING OF PATTERNED PHOTOVOLTAIC MATERIALS

(75) Inventors: Thomas Hunt, Oakland, CA (US); Christopher Rivest, Berkeley, CA (US); Mark Topinka, Berkeley, CA (US); Butrus T. Khuri-Yakub, Palo Alto, CA (US)

Correspondence Address: FENWICK & WEST LLP, SILICON VALLEY CENTER, 801 CALIFORNIA STREET, MOUNTAIN VIEW, CA, 94041, US

(73) Assignee: SUNPRINT INC., Berkeley, CA (US)

(21) Appl. No.: 12/329,325

(22) Filed: Dec. 5, 2008

Related U.S. Application Data
(60) Provisional application No. 61/012,325, filed on Dec. 7, 2007.
(60) Provisional application No. 61/072,340, filed on Mar. 31, 2008.

(51) Int. Cl. H01L 31/00; B41J 29/38

(52) U.S. Cl. 136/252; 347/14

(57) ABSTRACT

Photovoltaic material is printed on a substrate using acoustic printing, to produce solar cells. Acoustic printheads are configured to eject droplets of photovoltaic material to positions on the substrate, responsive to focused acoustic energy provided by acoustic ejectors in the acoustic printheads, to print a film of the photovoltaic material. A positioning system is configured to position the acoustic printheads with respect to the substrate. A feedback system controls the acoustic ejection of the droplets of photovoltaic material by the acoustic printheads or the positioning of the acoustic printheads with respect to the substrate by the positioning system, based on feedback data indicative of characteristics of the printed film. The acoustic printheads are designed optimally for printing of photovoltaic material for solar cells in single scans in only one direction of the substrate. Solar cells can be manufactured at low cost and with high throughput using acoustic printing.

### CROSS-REFERENCE TO RELATED APPLICATIONS

This application claims priority under 35 U.S.C. § 119(e) from co-pending U.S. Provisional Patent Application No. 61/012,325, entitled “Focused acoustic deposition of thin films, layers of films, or patterns of photovoltaic, conductive, or insulating materials,” filed on Dec. 7, 2007, and from co-pending U.S. Provisional Patent Application No. 61/072,340, entitled “Patterned film deposition with ultrasonically induced material ejection,” filed on Mar. 31, 2008, both of which are incorporated by reference herein in their entirety.

### BACKGROUND OF THE INVENTION

1. Field of the Invention

The present invention relates generally to the use of focused acoustic energy for depositing materials for use in solar photovoltaic cells, modules, and related systems.

2. Description of the Related Arts

Photovoltaics convert sunlight into electricity, providing a desirable source of clean energy. Some examples of current commercial photovoltaic solar cells are made of crystalline silicon and thin film (CdTe (Cadmium Telluride), CIGS (Copper-Indium-Gallium-Diselenide), or amorphous silicon) as well as polymer (P3HT/PCBM (poly(3-hexylthiophene)/phenyl-C61-butyric acid methyl ester) and derivatives).

However, the production of photovoltaics is limited by the high cost of fabricating such devices. Conventional manufacturing techniques for thin film photovoltaic devices are expensive. Most of these techniques require vacuum environments which drastically increase the capital cost, maintenance cost, and material cost required to manufacture thin film photovoltaic devices. Examples of such conventional manufacturing techniques are: Plasma Enhanced Chemical Vapor Deposition (PECVD), Chemical Vapor Deposition (CVD), Closed Space Sublimation (CSS), and Vapor Transport Deposition (VTD). Furthermore, these conventional techniques generally have very poor material use efficiency, as they deposit material non-specifically inside a deposition chamber, thereby significantly increasing the total cost of the photovoltaic module. In addition, as these methods deposit material over the entire substrate, the layers need subsequent partitioning or scribing into a series of interconnected cells to produce a photovoltaic module. Partitioning or scribing is relatively slow, expensive, prone to yield problems, and wasteful of the material between cells and near the module edges.

On the other hand, conventional printing techniques exist, yet none of the conventional printing techniques are well suited to the manufacture of thin film photovoltaic modules. For example, conventional screen printing is low cost, but is difficult to align precisely over large areas, and results in layers with a minimum thickness of 10 microns (high material use), with poor resultant layer uniformity, which is unsuitable for some layers in solar modules or cells. Conventional roll-to-roll printing or roller printing (such as gravure or off-set printing) is difficult to adapt to stiff substrates, such as glass, that may be desirable for use in solar modules, and pattern edges typically have poor thickness uniformity. In addition, the contact of roll-to-roll or roller printing can damage previously patterned layers. Conventional inkjet printing severely constrains ink composition to a narrow range of surface tensions, viscosities, suspended particle size, and particle loading, which is generally undesirable for printing a variety of material inks for films used in photovoltaics. Also, conventional inkjet printers often clog or have insufficient drop placement accuracy due to the method in which drops are formed at the exit nozzle of an inkjet printer. Such attributes are undesirable in the formation of photovoltaic cells, as lack of drop placement accuracy decreases film uniformity, and nozzle clogging can cause voids in the material layers of the photovoltaic cell, thereby destroying the device, or severely limiting its efficiency, and drastically lowering device yield. Even if nozzles do not become completely clogged, partial clogging can drastically effect the size of ejected droplets and hence the thickness of the resulting film.

Acoustic ink printing is a unique printing method in which emitters launch converging acoustic beams into a pool of ink, with the angular convergence of the beam being selected so that it comes to focus at or near the free surface (i.e., the liquid/air interface) of the ink pool. Controls are provided for modulating the radiation pressure which each beam exerts against the free surface of the ink. This permits the radiation pressure from each beam to make brief, controlled excursions to a sufficiently high pressure level to overcome the restraining force of surface tension, whereby individual droplets of ink are emitted from the free surface of the ink on command, with sufficient velocity to deposit them on a nearby surface. However, conventional acoustic printing devices have not generally been successfully commercialized and methods have not been developed with sufficient throughput, alignment, and control for solar cell manufacturing. For example, lab scale prototype acoustic printers have been designed for droplet-on-demand printing of documents and biological materials, but not for uniform coating of droplets across large regions to make patterned films at low cost and high through-put. Also, conventional acoustic printers are not capable of printing ink with precise alignment to previously patterned layers.

### SUMMARY OF THE INVENTION

Embodiments of the present invention include an apparatus and a method for acoustic printing of photovoltaic material on a substrate. One or more acoustic printheads including a plurality of acoustic ejectors are configured to eject droplets of material used in the production of a photovoltaic cell or module (referred to as “photovoltaic material” herein), to controlled positions on the substrate, using focused acoustic energy, to print a patterned film of the photovoltaic material on the substrate. A positioning system is configured to position the acoustic printheads with respect to the substrate. In addition, a feedback system is coupled to the acoustic printheads and the positioning system, and is configured to control the acoustic ejection of the droplets of photovoltaic material by the acoustic printheads or the positioning of the acoustic printheads by the positioning system, based on feedback data indicative of characteristics of the printed film.

Various designs of the acoustic ejectors and acoustic printheads (comprising a plurality of acoustic ejectors) are provided according to the embodiments of the present invention. For example, in one embodiment, acoustic printheads may span the entire length of the substrate in one direction, so that the acoustic printheads can print the patterned film while the substrate is moved only in a single direction with respect to the acoustic printheads or while the acoustic printheads are moved only in a single direction with respect to the substrate.

The apparatus and method of acoustic printing of photovoltaic material according to various embodiments of the present invention have the advantage that solar cells can be manufactured with drastically reduced fabrication cost, improved speed, reduced material waste, and high throughput, compared with conventional methods of fabricating solar cells or conventional printing methods.

The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

The teachings of the embodiments of the present invention can be readily understood by considering the following detailed description in conjunction with the accompanying drawings.

FIG. 1 illustrates a process used to print and pattern photovoltaic cells and materials using focused acoustic printing, according to one embodiment of the present invention.

FIG. 2 illustrates an acoustic printing system that can be used to pattern films onto a substrate to produce photovoltaic solar cells, according to one embodiment of the present invention.

FIG. 3A illustrates how an acoustic ejector ejects droplets of material to form patterned films onto a substrate, according to one embodiment of the present invention.

FIG. 3B illustrates several different focused acoustic print-head designs that could be used to eject droplets of material to form patterned films, according to various embodiments of the present invention.

FIG. 4A, FIG. 4B, FIG. 4C, FIG. 4D, and FIG. 4E illustrate several different focused acoustic print-head arrays that could be used to eject droplets of material to form patterned films, according to various embodiments of the present invention.

FIG. 5A and FIG. 5B illustrate top views and FIG. 5C, FIG. 5D, FIG. 5E, FIG. 5F, and FIG. 5G illustrate side views of a variety of printing and ink overlay patterns which could be used in the process of patterning ink to make a photovoltaic cell, according to various embodiments of the present invention.

FIG. 6 illustrates a process for manufacturing a photovoltaic module with patterns formed by aligned acoustic printing and material scribes, according to one embodiment of the present invention.

FIG. 7 illustrates a process for printing feedback that allows for continuous monitoring and adjustment of the acoustic printing process to optimize film characteristics, according to one embodiment of the present invention.

### DETAILED DESCRIPTION OF EMBODIMENTS

The Figures (FIG.) and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable similar or like reference numbers may be used in the figures and may indicate similar or like functionality. The figures depict embodiments of the present invention for purposes of illustration only. One skilled in the art will readily recognize from the following description that alternative embodiments of the structures and methods illustrated herein may be employed without departing from the principles of the invention described herein.

According to various embodiments of the present invention, focused acoustic printing technology is used to fabricate low-cost, high-performance solar cells. A variety of printhead array structures are customized for use in the acoustic printing process to produce the solar cells. Also, a process utilizes the focused acoustic printing technology and printhead array structures to fabricate solar cells and modules. According to one embodiment, the focused acoustic printer may include a positioning and alignment system to locate the printheads relative to the substrate, a feedback system to control the printing process, and a scribing system aligned with the printheads to selectively remove excess material before or after printing.

Turning to the figures, Figure (FIG.) 1 illustrates a process used to pattern photovoltaic cells and materials using focused acoustic printing, according to one embodiment of the present invention. The acoustic printing process 150 utilizes a computer 10, one or more acoustic printheads 11, a positioning system 13, and a feedback system 12.

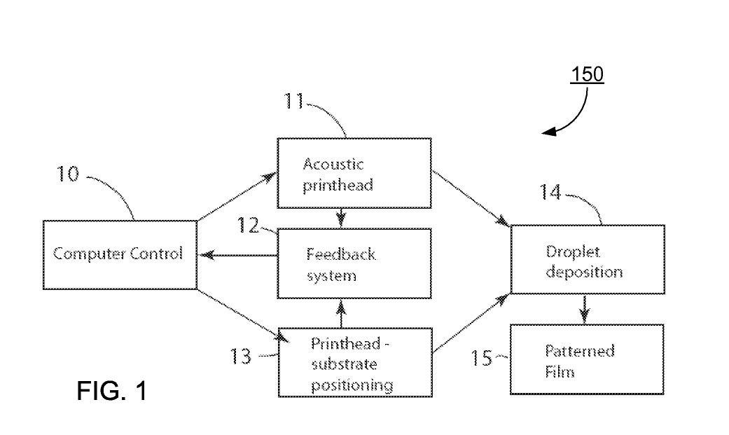

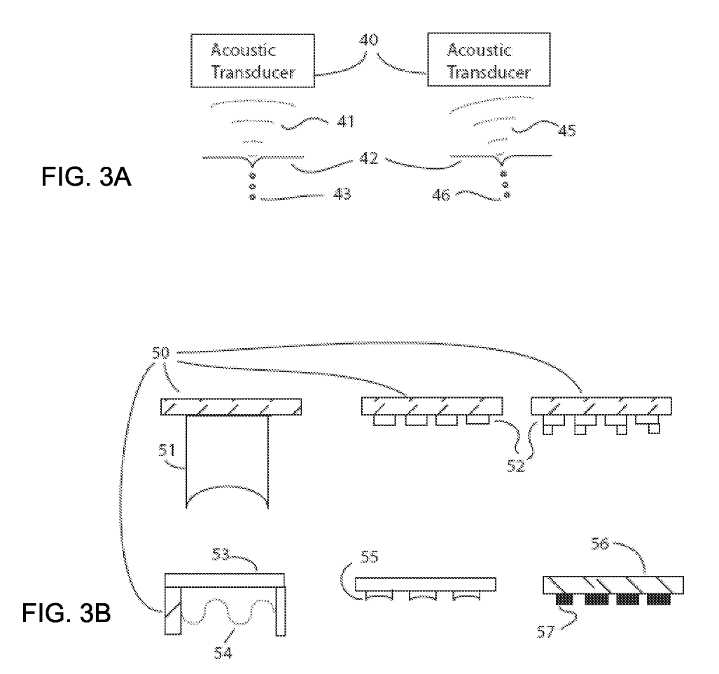

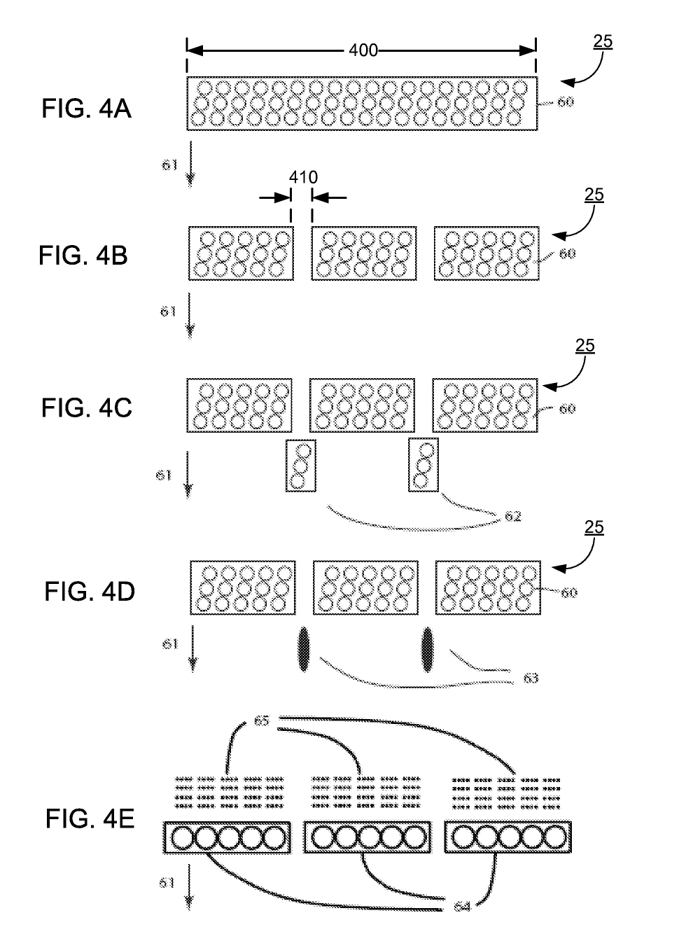

The acoustic printheads 11 are capable of droplet ejection. Specifically, focused acoustic printheads 11 are made up of a plurality of focused acoustic ejectors (explained in detail in FIGS. 3 and 4), each ejector being configured to focus acoustic energy on a spot at the surface of a liquid (not shown in FIG. 1), ejecting material droplets onto controlled positions on a substrate (not shown in FIG. 1). The basic principles of acoustic printing are explained in detail in, for example, U.S. Pat. No. 4,697,195 issued to Quate et al. on Sep. 29, 1987. However, the acoustic printing process and apparatus according to the various embodiments are significantly improved over conventional acoustic printing techniques for low-cost, high through-put printing of solar cells. The substrate may be glass, metal foil, plastic, or a combination thereof. The substrate may also include previously deposited material layers onto which additional material layers are deposited using focused acoustic ejection with the acoustic printheads 11. As will be explained in more detail below with reference to FIGS. 3A and 3B, the focused acoustic energy can be provided in the acoustic ejectors using acoustic transducers combined with acoustic lenses, acoustic Fresnel lenses or phase plates, as well as surface acoustic wave transducers, capacitive micro-machined transducers, standing wave transducers, or 2-dimensional standing wave transducers. Furthermore, each acoustic transducer may provide acoustic energy to a single acoustic lens or to an array of acoustic lenses. The final resulting deposited films may have desirable electrical properties such as high or low electrical resistance, semiconductor properties and photovoltaic properties. The films may also have desirable optical properties, being transparent, transparent to certain wavelengths of light, opaque, or reflective, for use in solar cells.

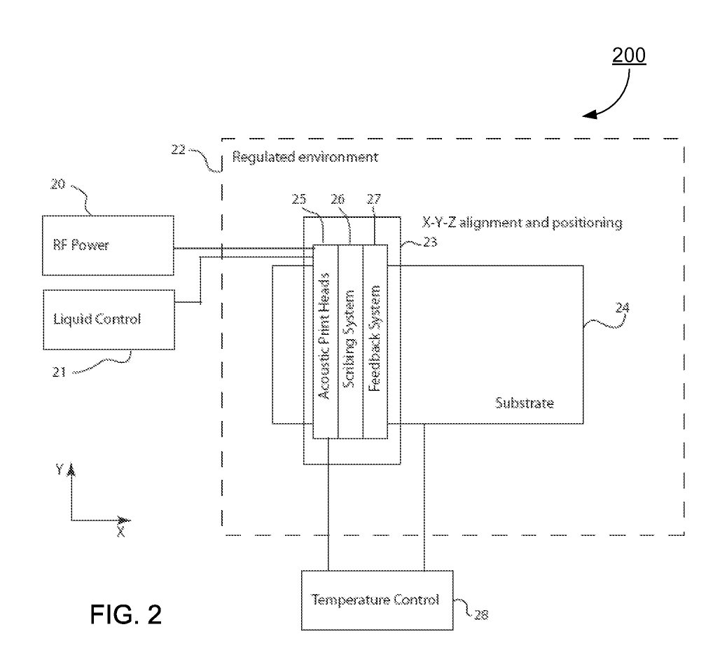

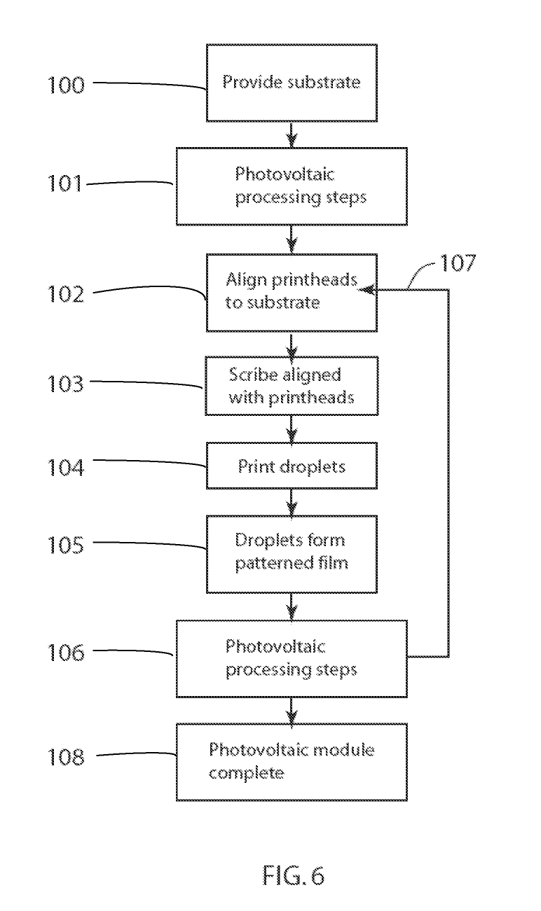

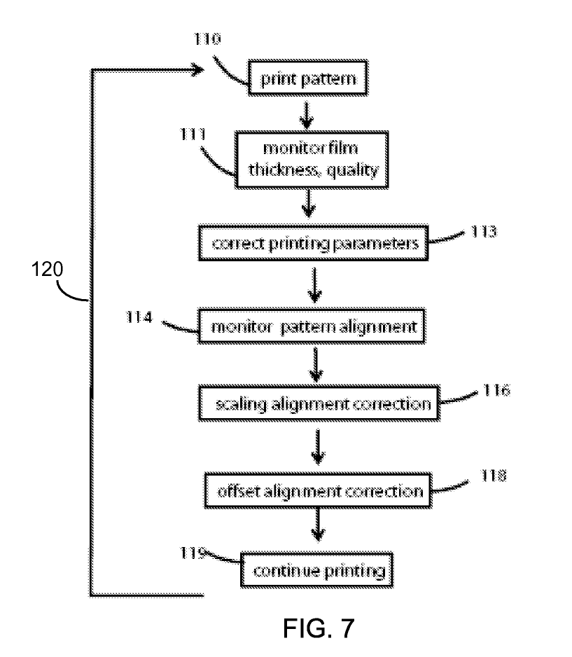

Computer 10 controls the focused acoustic printhead 11 as well as a substrate and/or printhead positioning system 13. Computer 10 sends commands to acoustic printhead 11 to eject droplets 14 of film material from the focused acoustic printhead 11 and print a patterned layer of material ink 15 precisely registered to the substrate or previous layers, of precisely controlled shape, thickness, and composition. Also, as will be explained in more detail below with reference to FIGS. 2 and 7, active feedback system 12 provides additional control feedback information to computer 10 to fine tune the control of printhead-substrate positioning system 13 or the acoustic energy in acoustic printhead 11 based on feedback data indicative of the monitored characteristics of the deposited film 15. At the same time as or separate from the film printing using the focused acoustic printhead 11, the deposited films can be scribed, heated, annealed, chemically treated, cleaned, dissolved, or otherwise modified, and the process can be repeated until all necessary layers and patterns have been deposited and processed onto the substrate to fabricate solar cells or modules. More details regarding the process of fabricating solar cells using focused acoustic printheads are set forth below with reference to FIG. 6.

FIG. 2 illustrates an acoustic printing system that can be used to pattern films onto a substrate to produce photovoltaic solar cells, according to one embodiment of the present invention. The acoustic printing system 200 includes acoustic printheads 25, a scribing system 26, a feedback system 27, X-Y-Z alignment and positioning system 23, a temperature control system 28, RF power source 20, and a liquid control system 21. Liquid control system 21 provides ink material to acoustic printheads 25 for printing of patterned films of the ink material onto substrate 24. The ink material can consist of a wide range of substances useful in the fabrication of photovoltaic cells and modules, a more complete discussion of which is included later herein.

A substrate 24 is positioned relative to the acoustic printheads 25 and scribing system 26 in X, Y, and Z directions by the alignment and positioning system 23 inside a regulated environment 22. The positioning system 23 can preferably control the relative position of the acoustic printheads 25 with respect to the substrate 24 within 10 microns in X, Y directions, more preferably within 1 micron in X, Y directions, and preferably within 50 microns in the Z direction, and more preferably within 5 microns in the Z direction.

RF power 20 is provided to acoustic printheads 25. RF power 20 is modulated as the substrate 24 and acoustic printheads 25 are moved past each other, causing a series of small droplets of ink material to be printed onto the substrate in the desired pattern. Some embodiments of the acoustic ejectors used in the printheads are explained in FIGS. 3A and 3B, while the full printheads are explained in more detail below with reference to FIGS. 4A through 4E. One embodiment of a scribing system is explained in more detail below with reference to FIG. 4D.

The regulated environment 22 allows for the chemical makeup, temperature, pressure and other aspects of the atmosphere surrounding the printheads 25 and the substrate 24 to be controlled to be optimum for acoustic printing of the films of material. For example, environmental regulation 22 includes controlling the vapor pressure of a solvent or other chemical in the environment. By changing the atmosphere between dry and solvent-saturated, the drying process of the ink can be slowed down or sped up to allow for better control of droplet coalescence and spreading and of resulting deposited film properties. By slowing down the drying of the ink, neighboring ink droplets have more of an opportunity to fuse together (if so desired), while by speeding up the drying of the ink, sharper features can be defined (if so desired).

Feedback system 27 is comprised of, but is not limited to, optical and temperature readouts to correct for temperature drift in the regulated environment 22, and thickness monitors to ensure uniform coatings across the width of the solar cell on the substrate 24.

Another component of the feedback system 27 is the precise initial and periodic calibration of the ejection properties of the individual ejectors that go into making up the acoustic printheads 25. Due to manufacturing imperfections, it is unavoidable that there will be some variability in the ejection properties of different ejectors. However, while individual ejectors of the acoustic printheads 25 might have slightly different characteristics, the long-term stability of the ejector properties of focused acoustic ejectors makes a precise initial calibration and correction utilizing this feedback system highly effective. Once the slight differences in drop size, power, or other characteristics between nozzles have been characterized by feedback system 27, such differences can be corrected through adjustments to the power or length of pulses sent to different ejectors, resulting in printheads 25 capable of printing uniform films over a relatively long period of time. Such correction is not possible with inkjet or other printing technologies that slowly and unpredictably change deposition properties such as thickness uniformity, pattern edge uniformity, etc. The ability to calibrate a set of ejectors, correcting for inevitable manufacturing imperfections is a major advantage for focused acoustic printing over other types of printing such as inkjet printing, screen printing, or gravure. The feedback system 27 allows for one printhead to print films of excellent uniformity and reproducibility over a long period of time. Additional details of the feedback system 27 are set forth below with reference to FIG. 7.

The acoustic printing system 200 prints material layers on substrate 24 while moving the substrate 24 in only one direction (X-direction) with respect to the printheads 25 or moving the printheads 25 in only one direction (X-direction) with respect to the substrate 24. This is made possible by taking advantage of the high degree of uniformity and clog-free operation possible with focused acoustic printing as well as a set of printheads which span the entire width (Y-axis in FIG. 2) of the substrate 24 or desired pattern. Thus, substrate 24 can be moved smoothly and quickly only in the X-direction underneath the printheads 25, or the printheads 25 can be moved only in the X-direction above the substrate 24. The specifics of the printheads that enable such one dimensional movement are detailed below with reference to FIG. 4A. The printheads 25 may be comprised of slightly staggered but overlapping focused acoustic printing elements which eject a uniform and continuous sheet of material ink in one pass, eliminating the need for slow and costly raster scanning hardware and software. In this way, superior film uniformity and high print speed (as compared to ink-jet and other conventional printing techniques) can be obtained, both of which enable the success of printed solar cells.

The liquid control system 21 allows the acoustic printing system 200 to maintain a constant level, composition, temperature, mixing, and thickness of ink material, and can be linked to the feedback system 27 to allow for a closed loop monitoring of these characteristics both through direct measurements on the ink as well as through real time optical, electrical, thermal, ultrasonic or other monitoring of the actual printed material. The connection of the liquid control system 21 to the feedback system 27 is useful in the field of solar cell fabrication, since the electrical properties of the resultant devices can depend sensitively on the thickness, granularity, and crystallinity of the resultant layers.

An additional feature included in the liquid control system 21 and printheads 25 is background ultrasonic mixing to keep particles uniformly suspended in the ink. By transmitting a low-level or off-resonance acoustic signal during the time periods between ejecting droplets, ink can be mixed and the particles can be kept evenly suspended even for periods of the printing process where a set of acoustic ejectors are inactive. In this way, low-viscosity solvents, high particle loading, or larger particle sizes can be accommodated into the printing process, allowing for a wider range of possible inks to be used with the acoustic printing system 200.

Another element of the feedback system 27 that is helpful in printing precisely positioned, patterned, and aligned layers on substrate 24 is the temperature control system 28 which allows for the controlled heating, cooling, stretching, or compressing of the printheads 25 and/or substrate 24 to accommodate thermal expansion or drift in the substrate 24 and/or printheads 25. One way to close the thermal expansion feedback loop is by printing test patterns at the corners of a solar panel and optically (or otherwise) measuring their position, size, and orientation relative to other previously patterned features on the cell. Any differences in alignment can then be corrected by rotating, shifting, heating, cooling, expanding, or contracting the printheads 25 and/or substrate 24 (specifically with respect to the Y-direction here, but not limited to the Y-axis) to provide a precise match between the currently printed layer and previous layers.

Another feature of the temperature control system 28 when combined with the regulated environment 22 is to allow for printing of heated or cooled inks onto heated or cooled substrates 24. This allows for a number of benefits in the acoustic printing system 22, including high heating of substrate 24 leading to acoustically printed pyrolysis, control of ink viscosity and other properties through control of ink temperature, and freezing or solidifying of molten ink onto a cooled substrate 24.

FIG. 3A illustrates how an acoustic ejector ejects droplets of material to form patterned films onto a substrate, according to one embodiment of the present invention. Acoustic transducers 40 generate tonebursts of converging acoustic waves 41 that impinge on the surface of ink or liquid 42. If the tonebursts are of sufficient intensity, droplets 43 will be ejected from the liquid surface. Focused acoustic ejectors capable of adding a lateral component to the propagating acoustic waves 45 can eject droplets 46 at an angle that deviates from perpendicular to the surface of the liquid 42, allowing for droplets to be ejected along a variety of trajectories, steering the droplet ejection path without mechanical scanning. The standard deviation of drop placement accuracy is preferably 10 micron, and more preferably 1 micron, and still more preferably 100 nm.

FIG. 3B illustrates several different focused acoustic ejector designs that could be used to eject droplets of material to form patterned films, according to various embodiments of the present invention. In one embodiment, a piezoelectric element 50 may produces acoustic waves 41 that may be focused by an acoustic lens (or plurality or lenses) 51, acoustic phase plate(s) or Fresnel lens(es) 52 with single or multiple layers. In another embodiment, a standing acoustic wave 54, in one or two dimensions, can be produced in a cavity 53 for droplet ejection at the wave maxima (peaks) of the standing acoustic wave 54. In still another embodiment, capacitive transducers 55 can be actuated with varying amplitude and phase to produce a steerable, focused acoustic beam. In still another embodiment, surface acoustic wave material 56 can be actuated with electrodes 57 in such a manner as to generate a focused acoustic beam 41. A number of other different ejector designs may also be used for steering of the ejected droplets. Addressable piezo elements under an acoustic lens 51, addressable electrodes 57 on surface acoustic wave material 56, and addressable capacitive transducers 55 are examples of transducers capable of droplet steering when the elements are provided with signals of appropriate amplitude and phase. In addition, parametric pumping of liquid with a sufficient intensity of acoustic energy can also be used in droplet generation.

The focused acoustic ejectors are grouped into ejector arrays and arranged to make printheads particularly suited for patterned photovoltaic material deposition. The printheads may contain a plurality of focused acoustic ejectors arranged to provide continuous droplet coverage over the width or length of a desired material film. Specifically, printheads, comprising arrays of focused acoustic ejectors, can be sized and arranged to produce films of a material that correlate to the exact width of a thin film photovoltaic cell, The cell's length is determined by the movement of either the printheads or the movement of the substrate. The ejector arrays that make up a printhead may be spaced apart from one another such that each unit solar cell is electrically isolated from the next solar cell.

FIG. 4A, FIG. 4B, FIG. 4C, FIG. 4D, and FIG. 4E illustrate several different focused acoustic print-head arrays 25 that could be used to eject droplets of material to form patterned films, according to various embodiments of the present invention. In each of these embodiments, rows of focused acoustic ejectors 60 are positioned slightly staggered from each other so as to provide a single pass, raster-free (if so desired) method of printing the desired pattern on a substrate. One simple example is shown in FIG. 4A. Each row of ejectors 60 is offset by a precise amount which enables successive drops to combine into a continuous sheet, even though each individual focused acoustic ejector is larger and spaced further from its immediate neighbor than one drop diameter. In one embodiment, each printhead 25 has a width 400 that spans the entire width of a substrate. Thus, the substrate or printheads 25 are moved only in one direction 61 allowing a single-pass printing. This is beneficial over conventional printing techniques for printing symmetrical patterns in solar cells, and allows for a printing system highly suitable for solar cells. However, in other embodiments, a smaller printhead that spans the width of one or several strips of solar cells rather than the entire panel can be scanned multiple times down the length of a panel to create the desired stripes of solar cells.

The acoustic printhead shown in FIG. 4B is an extension of the printhead shown in FIG. 4A, which further enables the printing of solar cells with both high speed and high-precision. By eliminating, or deactivating, certain columns 410 of focused acoustic ejectors, precise patterns and gaps that may be needed in solar cells can be created. It is possible to incorporate these gap patterns 410 in a low-cost, high-speed way into the basic design of the printhead of FIG. 4A, because of the high degree of symmetry along one axis and repeated patterns that are often found in solar panels. The acoustic ejectors that make up each array can be individually actuated, or can be grouped together and actuated as groups by a single acoustic transducer.

FIG. 4C shows a slightly more complicated printhead design in which two different sets of focused acoustic ejectors (60 and 62) are placed in close proximity and precise alignment to each other on the printhead 25. Two (or more) different material inks may be deposited by the two (or more) individual sets of ejectors 60 and 62, but the relative lateral position of these materials could be precisely, permanently, and cheaply, set by the mechanical design of the printhead of FIG. 4C. Also, one set of ejectors (e.g., ejectors 62) could be dynamically shifted slightly with respect to another (left/right) (e.g., ejectors 60) within the printhead, allowing for differing alignment of the two (or more) constituent inks across the length of the solar panel, but still enabling very high speed printing and very precise relative alignment of the two (or more) constituent inks. Such printhead of FIG. 4C would be useful in the substantially simultaneous deposition of an active layer of a solar cell with a resist designed to keep the active layers in adjacent cells from bleeding into each other during the printing, drying, or annealing steps. Also, the printhead of FIG. 4C would be useful where precise, high speed, low-cost alignment of two different chemicals is needed, for example, when an etchant for a lower layer (e.g., for a transparent conductor) and the ink for an upper coating layer (e.g., CdS in a CdS/CdTe cell) of a solar cell is applied substantially simultaneously, obviating the need for alignment steps between the two layers. Yet another situation where the printhead of FIG. 4C would be useful is when printing two layers that can be annealed substantially simultaneously, for example, the window layer and the active layer of certain solar cells. By changing the relative positions of the two sets of ejectors 60, 62 slightly, either with actuators, or permanently by the design and construction of the printhead, different amounts of overlap or precise alignment between the two (or more) layers can be created.

FIG. 4D shows another possible printhead design, comprised of precisely aligned focused acoustic ejectors 60 and scribing devices 63 such as mechanical, laser, thermal, or chemical material removal devices. By combining the acoustic ejectors 60 and scribing devices 63 into one printhead, significant advantages in solar cell manufacturing speed, precision, and cost can be gained. For instance, in one embodiment, the set of scribes 63 may be laser scribes, and the set of focused acoustic ejectors 60 may print active-layer material (such as CdTe) for the solar cell. In this way, the CdTe patterns are automatically and precisely aligned to the scribed lines in the transparent conductor (ITO) and window layers (CdS) beneath, substantially simultaneously without additional steps. Processing steps which are automatically precisely aligned to each other can provide critical cost savings and improved yield in the solar cell fabrication process.

FIG. 4E shows the formation of patterned films by directional acoustic ejection. In one embodiment of the present invention, arrays of directional acoustic ejectors 64 are used to raster the ejected ink drops 65 quickly back and forth as the substrate is moved relative to the printhead slowly in the X-direction 61, reducing the number of individual acoustic ejectors while maintaining the advantages in speed and simplicity enabled by the single pass, single axis printing with a wide printhead as explained above with reference to FIG. 4A. The various printhead designs in FIGS. 4B, 4C, 4D, 4E are also applicable in combination with this technique of FIG. 4E. Finally, in another embodiment, directional acoustic ejectors are used to correct for slight alignment mismatch between the printhead and the underlying previously printed layers.

The printhead arrays according to the various embodiments of FIGS. 4A-4E may be separated into discreet units, for which each unit deposits material with a width that defines a photovoltaic cell, preferably 5 cm or less, more preferably 0.5-2 cm. The length of the photovoltaic cell printed from such arrays may be 5 cm or more, or more preferably 50 cm or more, or more preferably 200 cm or more. The printhead arrays include a sufficient quantity of acoustic ejectors to sufficiently cover the substrate, with a total width of 50 cm, or more preferably 100 cm, or more preferably 300 cm.

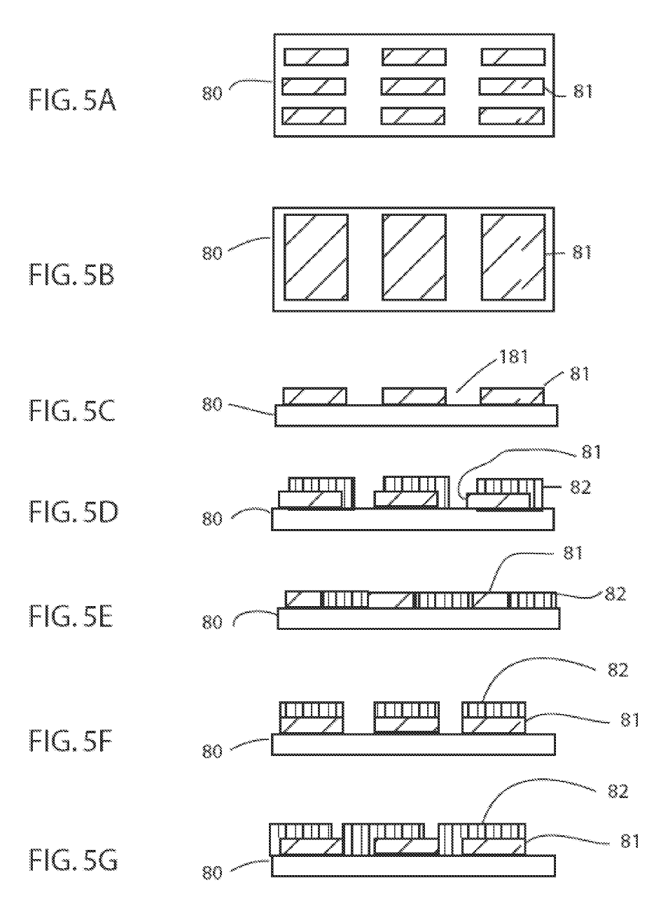

FIG. 5A and FIG. 5B illustrate top views and FIG. 5C, FIG. 5D, FIG. 5E, FIG. 5F, and FIG. 5G illustrate side views of a variety of printing and ink overlay patterns which may be used in the process of patterning ink to make a photovoltaic cell, according to various embodiments of the present invention. FIG. 5A shows top-down views of two-dimensional arrays 81 of patterns on the substrate 80, and FIG. 5B shows top-down view of one dimensional strips 81 of patterns on the substrate 80, both of which are useful in the fabrication of solar cells, and both of which could be printed. Additionally, fabrication of solar cells requires printing or creation of a material layer with precise relative alignment to an underlying layer. The printed patterns 81 may be from 10 nm to 1 mm thick. Uniform thickness of the printed layers 81 with preferably less than 50% thickness variation, more preferably less than 5% thickness variation, is preferred. Pattern edge variation of less than 1 mm, preferably less than 100 microns, and more preferably less than 10 microns, is also preferred.

Some examples of the types of patterns that may be desired, and which can all be realized using the inventions described herein, are shown in FIGS. 5C-5G. These schematics show relative alignment of one layer to another, and all combinations of the left or right edge alignments shown in these schematics can be fabricated according to the present invention. FIG. 5C shows the simplest possible non-continuous pattern—that of stripes 81 containing material and stripes 181 without material. The pattern of FIG. 5C could, for example, be useful for patterning decorative ink or conductive front-contact (window layer) pads for solar cells or patterning the active layer on top of the window layer. The pattern in FIG. 5D shows one layer 82 deposited to cover one edge (right-side) of the underlying layer 82 fabricated as in FIG. 5B. The pattern of FIG. 5E shows the layers 82 disposed in between the layers 81 fabricated as in FIGS. 5B and 5C. The pattern of FIG. 5E could, for example, be useful in printing a resist in between active regions of the solar cell to prevent spreading during printing, drying, annealing, or other future processing steps, or to print insulating stripes that would allow for later layers to be printed without shorting to the substrate in the solar cell. The pattern of FIG. 5F shows layer 82 deposited with both edges aligned to the edges of layer 81. The pattern of FIG. 5F is useful for printing two layers which are ideally exactly aligned, such as the active layer and top contact material of solar cells. The alignments shown in FIG. 5C through FIG. 5F can also be combined as needed. One example is shown in FIG. 5G, where the overlap alignment of FIG. 5D has been combined with the flush alignment of FIG. 5E. All of the alignments shown in FIGS. 5C-5G and combinations thereof are applicable to the two basic two-dimensional patterns shown in FIGS. 5A and 5B, that is, the extensions of the relative side view alignments in FIGS. 5C-5G can be applied to the relative alignments in both directions X and Y of the two dimensional matrix pattern in FIG. 5A or the one-dimensional stripes in FIG. 5B, or even to irregular, non-periodic patterns (not shown herein).

FIG. 6 illustrates a process for manufacturing a photovoltaic module with patterns formed by aligned acoustic printing and material scribes, according to one embodiment of the present invention. The present invention provides patterned layer formation by acoustic printing of droplets in controlled locations. To form a layer from a plurality of deposited droplets, the droplets may contain a suspension of particles (1 nm-10 microns in size) in a solvent or carrier fluid, chemical precursors that react to form the layer spontaneously, under the influence of heat, light, or chemicals, particles that may be melted or annealed together to form the film, particles that melt with the assistance of flux to form the film, particles that are sintered, or liquid metal or liquid polymer that solidifies to form the film. However deposited, whether in particle or precursor form, material layers may then be processed to achieve desired electrical or optical properties. Such processing steps may include but are not limited to annealing or sintering (in air or in a controlled atmosphere) at temperatures of 50-1500 degrees Celsius, doping, etching, scribing, or other forms of chemical, thermal or sonic treatments.

More specifically, referring to FIG. 6, a substrate is provided 100, and processing steps useful in fabricating photovoltaics such as vacuum deposition, sputtering, CVD, etc. can be applied 101. Subsequently, the acoustic printheads are aligned 102 to the substrate, which may be the original substrate, or the substrate now coated with one or more patterned or unpatterned films. Scribes that are aligned with the printheads (see e.g., FIG. 4D) may remove 103 undesired material from the printed films on the substrate by laser ablation, mechanical, thermal, or chemical means. Then, droplets of the desired ink material are printed 104 in a controlled pattern using the acoustic printheads according to various embodiments of the present invention. The droplets are then combined to form 105 a patterned film on the substrate. The droplets may be loaded with particles that form a film when the solvent evaporates. The droplets may also contain chemical precursors that form a film when in contact with other chemicals, or with the substrate which may be heated or cooled. The droplets may be composed of molten or dissolved metal or polymer which solidifies upon contact with the substrate. Then, more photovoltaic processing steps 106 may follow, such as annealing the printed film to improve its properties. If more patterned films are desired, the sequence of aligning, scribing, and printing can be repeated 107. Finally, after performing standard photovoltaic processing steps 106 such as module sealing and junction box mounting, a photovoltaic module is completed 108.

FIG. 7 illustrates a process for printing feedback that allows for continuous monitoring and adjustment of the acoustic printing process to optimize film characteristics, according to one embodiment of the present invention. The printing system includes a number of elements needed for printing uniform, well aligned films over large areas, as is necessary in the fabrication of solar cells, while doing so quickly using a single one-dimensional raster scan of the printhead. Specifically, a film is printed 110 using the acoustic printheads of the present invention, and the film characteristics (e.g., thickness and roughness) are monitored 111 using appropriate sensors. If the measured film characteristics deviate outside a desired range, printing parameter corrections are made 113 in real-time by adjusting parameters such as drop size, ink temperature and substrate temperature for the acoustic printheads 25 and temperature control system 28 (see FIG. 2). At the same time, pattern alignment is monitored 114 (i.e., how well the offset and width of the current pattern is matched to the underlying patterns) by direct imaging of the current and previously printed film. If any mismatch in the scaling of the current pattern to underlying patterns is detected by a real-time computer analysis of these images, (i.e., the width of the current pattern differs from underlying patterns), the scaling alignment correction is performed 116 using one of several correction methods. One way this scaling mismatch can be corrected is by applying heating or cooling to the printhead 25 or substrate 24 using temperature control system 28 (see FIG. 2). Because materials generally expand upon heating and shrink upon cooling, small mismatches in scale between the printed film and underlying patterned films can be corrected before they grow too large by expanding or shrinking the printhead or substrate through heating or cooling. Direct mechanical expansion or shrinking of the printhead 25 or substrate 24 is also possible. Likewise, if any small overall offset between the printed pattern and underlying patterns is detected, this is corrected through the offset alignment correction 118, by either shifting the printhead 25 with respect to the substrate 24, or using directional acoustic ejectors (see FIG. 3A) and changing the ejection angle slightly. As these corrections are going on, printing continues 119 and the feedback cycle repeats 120 until the entire pattern has been printed. In this way, small errors in film characteristics, scaling, and offset can be corrected during the printing of a panel before the errors become large enough to affect the final performance of the solar panel.

The techniques outlined herein can be used to deposit a wide range of materials needed in the manufacturing process of a photovoltaic cell or module. The ink material may be elements and/or compounds formed from (but not limited to): Ag, Cu, C, Cd, Te, Si, In, Ga, Se, S, Sn, Hg, Pb, Cl, Zn, Ti, N, O, H. These inks can be used to print material layers of, for example, CdTe, CdS, Cadmium Stannate, ITO (Indium Tin Oxide), FTO, Carbon paste, Carbon nanotube films, CIGS, Mo, CIS (copper indium selenide), ZTO (Zinc Tin Oxide), silicon, spin-on glass, and polymers used in organic solar cells including P3HT, PCBM (fullerene derivative [6,6]-phenyl-C₆₁-butyric acid methyl ester), PEDOT-PSS (Poly(3,4-ethylenedioxythiophene) poly(styrenesulfonate)), PBTTT (Poly(2,5-bis(3-tetradecyllthiophen-2-yl)thieno[3,2-b]thiophene)), TiO2 (titanium dioxide). These and other materials may be printed as particles in their elemental form, as particles in compound form, dissolved in solution, molten, as organometalics, as salts or in any other form that enables the resultant deposition of the desired material. Furthermore, the ink material may also be solvents or carrier fluids (or particle laden solvents or carrier fluids) including but not limited to water, propylene glycol, polypropylene glycol, ethanol, methanol, glycerol, ethylene glycol, polyethylene glycol, or mixtures thereof. Furthermore, the ink may or may not contain surfactants, binders, or other additives that alter the surface tension, viscosity, surface forces, or other properties of the carrier fluid, solvent, or particles to be printed. The inks can also comprise fluxes, etchants, detergents, dopants, glues, epoxies, and other substances useful in the manufacturing of photovoltaic cells or modules.

Acoustic printing of such material for manufacturing photovoltaic cells according to various embodiments of the present invention bypasses a number of time-consuming and costly steps, and makes possible new steps not used in conventional solar cell production techniques. Focused acoustic printing enables high-speed, low cost deposition of the various layers of a photovoltaic cell as well as the interconnects between those cells, forming the precisely aligned patterns necessary for a fully functioning large-scale solar panel at drastically reduced fabrication cost, with high speed, and with drastically reduced material waste. By moving to a non-vacuum environment (since acoustic printing does not require a vacuum environment), and with high material use efficiency, both capital and manufacturing costs for production of thin film photovoltaic modules are reduced. In addition, since acoustic printing is a non-contact printing method, films may be printed onto substrates without contact with the substrate and without damaging previous patterns already deposited on the substrate. Acoustic printheads can be constructed with a dense array of ejectors, allowing for high throughput operation in solar cell production.

Upon reading this disclosure, those of skill in the art will appreciate still additional alternative designs for an apparatus and methods for acoustic printing of photovoltaic materials. Thus, while particular embodiments and applications of the present invention have been illustrated and described, it is to be understood that the invention is not limited to the precise construction and components disclosed herein and that various modifications, changes and variations which will be apparent to those skilled in the art may be made in the arrangement, operation and details of the method and apparatus of the present invention disclosed herein without departing from the spirit and scope of the invention as defined in the appended claims.

What is claimed is:

1. An apparatus for acoustic printing of material used in production of photovoltaic modules on a substrate, the apparatus comprising:
one or more acoustic printheads including a plurality of acoustic ejectors, the acoustic printheads configured to eject droplets of said material used in production of photovoltaic modules to positions on the substrate, responsive to focused acoustic energy, to print films of said material; and
a positioning system configured to position the acoustic printheads with respect to the substrate.

2. The apparatus of claim 1, further comprising:
a feedback system coupled to the acoustic printheads and the positioning system, the feedback system configured to control the acoustic ejection of the droplets of said material by the acoustic printheads or the positioning of the acoustic printheads with respect to the substrate by the positioning system based on feedback data indicative of characteristics of the printed film of said material.

3. The apparatus of claim 1, further comprising:
a temperature control system configured to control a temperature of a regulated environment in which the acoustic printheads and the substrate are used, the feedback system further configured to control a temperature of the regulated environment based on the feedback data.

4. The apparatus of claim 1, wherein the feedback system is configured to compensate for initial differences in the acoustic ejectors caused by manufacturing imperfections.

5. The apparatus of claim 1, wherein the acoustic printheads print the film while the substrate is moved in only one direction with respect to the acoustic printheads or while the acoustic printheads are moved in only one direction with respect to the substrate.

6. The apparatus of claim 5, wherein the acoustic printheads span across an entire width of the substrate in a direction different from said only one direction of movement.

7. The apparatus of claim 1, wherein the acoustic ejectors are configured to steer directions at which the droplets are ejected.

8. The apparatus of claim 1, wherein the acoustic printheads comprise the acoustic ejectors in which a standing acoustic wave is formed in a cavity to eject the droplets at wave maxima of the standing acoustic wave.

9. The apparatus of claim 1, wherein the printheads include a plurality of the acoustic ejectors that are positioned staggered with respect to one another, offset by a predetermined distance, for the ejected droplets to combine into a continuous layer.

10. The apparatus of claim 1, wherein the printhead arrays include first printhead arrays for printing a first material, interspersed with second printhead arrays for printing a second material, to allow substantially simultaneous printing of both the first material and the second material automatically aligned on the substrate.

11. The apparatus of claim 1, wherein the printhead arrays are interspersed with scribing devices that are aligned with the printhead arrays to allow substantially simultaneous printing and patterning of the film using the printhead arrays and scribing devices, respectively.

12. A method of acoustic printing of material used in production of photovoltaic modules on a substrate, the method comprising the steps of:
positioning acoustic printheads with respect to a substrate, the acoustic printheads including a plurality of acoustic ejectors; and
acoustically ejecting droplets of said material used in production of photovoltaic modules to positions on the substrate, responsive to focused acoustic energy provided by the acoustic ejectors of the acoustic printheads, to print a film of said material.

13. The method of claim 12, further comprising the step of:
controlling the acoustic ejection of the droplets of said material by the acoustic printheads or the positioning of the acoustic printheads by the positioning system with respect to the substrate, based on feedback data indicative of characteristics of the printed film.

14. The method of claim 12, further comprising the step of:
controlling a temperature of a regulated environment in which the acoustic printheads and the substrate are used based on the feedback data.

15. The method of claim 12, wherein the step of acoustically ejecting droplets of said material comprises moving the substrate in only one direction with respect to the acoustic printheads or moving the acoustic printheads in only one direction with respect to the substrate.

16. The method of claim 12, wherein droplets of said material are acoustically ejected, positioned staggered with one another, offset by a predetermined distance, for the ejected droplets to combine into a continuous layer.

17. The method of claim 12, wherein the step of acoustically ejecting droplets of said material comprises acoustically ejecting droplets of both a first material and a second material substantially simultaneously, automatically aligned on the substrate, using first printheads interspersed with second printheads.

18. The method of claim 12, wherein the step of acoustically ejecting droplets of said material comprises simultaneously printing and patterning the film using the printhead arrays and scribing devices, respectively, the scribing devices being interspersed and aligned with the printhead arrays.

19. The method of claim 12, wherein the step of acoustically ejecting droplets of said material comprises printing a second layer of said material aligned with a first, underlying layer of said material.

20. The method of claim 12, wherein the step of acoustically ejecting droplets of said material comprises printing a second layer of said material overlapped with a first, underlying layer of said material.

21. A solar cell produced by a process of acoustic printing of material used in production of photovoltaic modules on a substrate, the method comprising the steps of:
positioning acoustic printheads with respect to a substrate, the acoustic printheads including a plurality of acoustic ejectors; and
acoustically ejecting droplets of said material used in production of photovoltaic modules to positions on the substrate, responsive to focused acoustic energy provided by the acoustic ejectors of the acoustic printheads, to print a film of said material.

22. The solar cell of claim 21, wherein the step of acoustically ejecting droplets of said material comprises moving the substrate in only one direction with respect to the acoustic printheads or moving the acoustic printheads in only one direction with respect to the substrate.
